(19) United States
(12) Patent Application Publication
(10) Pub. No.: US 2026/0134916 A1
(43) Pub. Date: May 14, 2026

(54) COMPENSATION CURRENT FOR A PCM MEMORY

(71) Applicant: STMicroelectronics International NV., Geneva (CH)

(72) Inventor: Faress TISSAFI DRISSI, Crolles (FR)

(73) Assignee: STMicroelectronics International N.V., Geneva (CH)

(21) Appl. No.: 19/381,216

(22) Filed: Nov. 6, 2025

(30) Foreign Application Priority Data
Nov. 8, 2024 (FR) FR2412227

(51) Int. Cl. G11C 13/00

(52) U.S. Cl. CPC G11C 13/0069; G11C 13/0004; G11C 2013/0071; G11C 2013/0092; G11C 2213/79

(57) ABSTRACT

The present disclosure relates to a memory block comprising rows and columns of phase-change memory cells. A first MOS transistor couples a supply voltage to an input receiving a reference current, and has its gate connected to the input. For each column, a second transistor couples the supply voltage to a corresponding output coupled to the column. A conductive rail connects the input to the gates of the second transistors. A circuit selects columns such that, during a writing operation, a write current pulse flows through each selected column. Another circuit supplies the conductive rail, at the start of the write current pulses, with a compensation current pulse determined by the selected columns.

### PRIORITY CLAIM

This application claims the priority benefit of French Application for Patent No. FR2412227, filed on November 8, 2024, the content of which I s hereby incorporated by reference in its entirety to the maximum extent allowable by law.

### TECHNICAL FIELD

The present disclosure relates generally to electronic circuits and, more particularly, to Phase Change Memory (PCM) type memories, which are memories comprising at least one block of a plurality of PCM memory cells, or, put another way, at least one PCM memory block.

### BACKGROUND

A Phase Change Memory (PCM) type memory block comprises a plurality of memory cells arranged in a memory cell matrix, that is, in rows and columns of memory cells.

Each PCM memory cell is configured to store an item of information, for example a bit, having a value determined by a resistance value of the memory cell.

Writing or programming a value in a memory cell therefore implies programming a state, for example crystalline or amorphous, of a phase-change material in the memory cell, so as to program a resistance value for the memory cell.

The programming of a state of the phase-change material of a memory cell, and therefore of the state of the memory cell, is accomplished by circulating a current pulse in the memory cell, the shape of the pulse determining the state programmed in the memory cell.

This current pulse is usually generated from a copy of a reference current supplied, for example, by a digital-to-analog converter controlling the gate of a transistor.

To speed up a writing operation in the PCM memory block, it would be desirable to be able to program memory cells belonging to each of the various columns simultaneously. However, this poses a number of problems.

There is a need for a PCM memory block that allows a plurality of memory cells, each belonging to different columns of the memory block, to be written simultaneously.

There is a need to address some or all of the drawbacks of known PCM memory blocks.

### SUMMARY

An embodiment provides a PCM memory block comprising: a plurality of phase-change memory cells arranged in rows and columns; a first circuit comprising: at least one first MOS transistor coupling a supply voltage to an input of the first circuit configured to receive a reference current, and having its gate connected to said input; for each column, at least one second transistor coupling the supply voltage and a corresponding output of the first circuit coupled to said column; and a conductive rail connecting said input to the gates of the second transistors; for each column, at least one third MOS transistor coupling said column to the corresponding output of the first circuit; a second circuit configured to: receive a first signal indicating columns to be written during a writing operation, and a second signal controlling the writing operation; and control the third MOS transistors based on the first and second signals, so that, during the writing operation, a write current pulse flows in each selected column; and a third circuit configured to: receive a third signal indicating a number of selected columns and a fourth signal indicating a start of write current pulses in the selected columns; and supply to the conductive rail, at the start of the write current pulses, a pulse of a compensation current determined by the third and fourth signals.

According to one embodiment, the compensation current pulse is determined based on the third and fourth signals so as to compensate for a voltage variation on said rail resulting from a switching to a conductive state of the third MOS transistors of the selected columns at the start of the write current pulses.

According to one embodiment, for each column, said at least one second MOS transistor coupling the supply voltage and the corresponding output of the first circuit is arranged in a current mirror configuration with said at least one first MOS transistor.

According to one embodiment, the fourth signal determines a start of the compensation current pulse, and the third signal determines a maximum value of the compensation current pulse.

According to one embodiment, the third signal further comprises an indication of a maximum value of the write current pulses during the writing operation.

According to one embodiment, the second signal indicates a start and an end of the write current pulses flowing in the selected columns.

According to one embodiment, the fourth signal is determined at least in part by the second signal.

According to one embodiment, the third circuit is further configured to receive a signal for selectively activating and deactivating the supply of the compensation current pulse to said rail.

According to one embodiment, the third circuit comprises a single output connected to said rail and configured to provide said compensation current pulse.

According to one embodiment, the third circuit comprises a plurality of parallel capacitors each coupled to a first node by a first switch, and a second switch coupling the first node to the output of the third circuit, the third circuit being configured to pre-charge the capacitors prior to the writing operation, to close the second switch at the start of the compensation current pulse, and to close all or some of the first switches prior to the closure of the second switch based on the third signal.

According to one embodiment: the third circuit comprises, for each column, a corresponding output connected to the gate of said at least one second MOS transistor coupled to said column; the third circuit comprises, for each column, a sub-circuit configured so as to supply at the output of the third circuit corresponding to that column, a first current pulse starting with the compensation current pulse if said column is selected; and the compensation current pulse corresponds to the set of first pulses.

According to one embodiment: each sub-circuit comprises: a plurality of parallel capacitors each coupled to a first node of said sub-circuit by a first switch, and a second switch coupling said first node of said sub-circuit to the output of the third circuit to which this sub-circuit is connected; and each sub-circuit is configured to: pre-charge said capacitors prior to the writing operation; close its second switch at the start of the compensation current pulse if the column corresponding to the sub-circuit is selected; and close all or some of the first switches prior to closing the second switch based on the third signal.

According to one embodiment, for each column, the sub-circuit corresponding to this column is configured to receive a control signal from said at least a third switch corresponding to this column, and to control the switching of its second switch to the conducting state based on this control signal.

One embodiment provides a memory comprising at least one memory block as defined above, and a circuit configured to supply the reference current.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 shows an example of a PCM memory block;

FIG. 2 shows a curve illustrating a drawback of the memory block shown in FIG. 1;

FIG. 3 shows an example of a PCM memory block;

FIG. 4 shows an example of a circuit from the memory block shown in FIG. 3;

FIG. 5 shows an example of another circuit from the memory block shown in FIG. 3; and

FIG. 6 shows an example of a variant of the PCM memory block shown in FIG. 3; and

FIG. 7 shows an example of a circuit from the memory block shown in FIG. 6.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10 % or 10°, and preferably within 5 % or 5°.

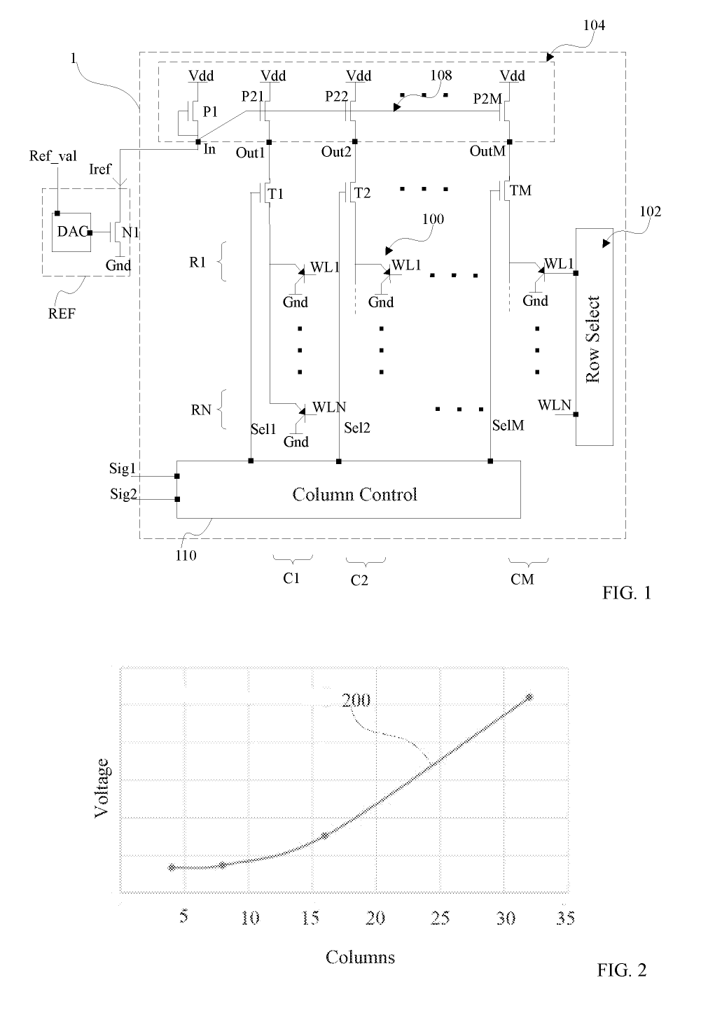

FIG. 1 shows an example of a PCM memory block, referenced 1 and delimited by dotted lines in FIG. 1.

The memory block 1 comprises a plurality of phase-change memory cells 100, represented in FIG. 1 by bipolar transistors. In FIG. 1, only one memory cell 100 is referenced to avoid overloading the figure.

The memory cells 100 are arranged into rows Ri and columns Cj, where i and j are integer indices, i being in the range 1 to N, with N being an integer greater than or equal to 2, and j being in the range 1 to M, with M being an integer greater than or equal to 2. By way of example, the index j is greater than 5, for example greater than 10. In FIG. 1, in order not to overload the figure, not all of the rows Ri and columns Cj of the memory cells 100 are shown, and the rows Ri, respectively the columns Cj, that are shown are only partially represented.

Typically, the memory cells in each column Cj are coupled, for example connected, to the same column conductive rail capable of conducting a programming (or writing) current pulse. Typically, the memory cells 100 in the same row Ri all receive the same selection signal WLi (WL1 and WLN in FIG. 1), the signals WLi being used to select the cells 100 in a given row Ri and to deselect the cells 100 in other rows Ri. Thus, when a write current pulse is supplied to a given column Cj, only the memory cell 100 whose row Ri is selected receives this write current pulse and is programmed by this current pulse. By way of example, the signals WLi are supplied by a row selection circuit 102 forming, for example, part of the block 1.

The block 1 comprises a circuit 104. The circuit 104 is configured to receive a reference current Iref and to supply copies of this current to the columns Cj, in particular to the conductive rails of the columns to which the memory cells 100 of the columns are coupled, for example connected. Preferably, the current copies supplied to the columns Cj correspond to a current amplified with respect to the reference current Iref.

The circuit 104 comprises at least one MOS transistor P1, for example a P-channel transistor, coupling a supply voltage Vdd to an input In of the circuit 104, the input In being configured to receive the reference current Iref. The gate of the transistor P1 is connected to the input In. In the example shown in FIG. 1, the circuit 104 comprises only one transistor P1 with its conduction terminals coupled, for example connected, to the voltage Vdd and the input In respectively. By way of example, the voltage Vdd is positive with respect to a reference voltage, for example ground Gnd.

The circuit 104 also includes, for each column Cj, at least one MOS transistor P2j, for example a P-channel transistor like transistor P1, coupling the voltage Vdd to an output Outj coupled to that column Cj. In other words, the circuit 104 comprises M outputs OUTj, each connected to the corresponding column Cj. In the example shown in FIG. 1, for each column Cj, the circuit 104 comprises only one transistor P2j having its conduction terminals coupled, for example connected, respectively to voltage Vdd and to the corresponding output Outj.

The circuit 104 includes a conductive rail 108 connecting the gate of the transistor P1 to the gates of the transistors P2j.

Thus, for each column Cj, the circuit 104 comprises a current mirror formed by the transistor P1 and by the transistor P2j mirrored with respect to the transistor P1. The M current mirrors of the circuit 104 share the same transistor P1.

By way of example, the current Iref is supplied to the input In of the circuit 104 by a circuit REF configured to supply the current Iref. Preferably, this circuit REF is not part of the block 1, and may be shared between, or common to, a plurality of blocks 1 in a memory circuit comprising a plurality of blocks 1.

Preferably, the value of the current Iref can be modified over time, and the circuit REF receives a signal Ref_val, for example a digital signal, controlling the value of the current Iref.

By way of example, the circuit REF comprises a digital-to-analog converter DAC, for example controlled by the signal Ref_val, an analog output of the circuit DAC controlling the gate of a transistor N1, for example an N-channel transistor, having an on-state resistance which determines the value of the current Iref. Transistor N1 is part of the circuit REF or, alternatively, can be provided in each block 1, whereas the circuit DAC is preferably shared between a plurality of blocks. By way of example, transistor N1 couples the input In of the circuit 104 to a reference voltage, for example ground Gnd.

For each column Cj, the block 1 includes at least one column selection MOS transistor Tj. For each column Cj, the conductive or non-conductive state of the transistor(s) Tj determines whether a current can be supplied from the output Outj of the circuit 104 to flow through the corresponding column Cj. In the example shown in FIG. 1, for each column Cj, the transistor(s) Tj couple the corresponding output Outj of the circuit Tj to the column Cj, that is, for example, to the conductive rail of the column Cj to which the cells 100 of this column Cj are coupled, preferably connected. By way of example, in FIG. 1, for each column Cj, the block 1 comprises only one transistor Tj having a first conduction terminal coupled, preferably connected, to the column Cj, and a second conduction terminal coupled, preferably connected, to the corresponding output Outj of the circuit 104. In other examples not shown, for each column Cj, the block 1 comprises a plurality of transistors Tj connected in series between column Cj and the corresponding output Outj of the circuit 104.

The block 1 includes a column control circuit 110. The circuit 110 is configured to control the transistors Tj. For each column Cj, the circuit 110 supplies a control signal Selj for controlling the transistor(s) Tj.

More specifically, during a simultaneous writing operation in one or more columns Cj selected among the M columns Cj, the circuit 110 is configured to control transistors Tj so that a write current pulse flows in each of the selected columns Cj, and does not flow in the other columns Cj. The circuit 110 controls the transistors so that the write current pulses flowing in the selected columns start at the same time and end at the same time. By way of example, when the block 1 comprises only one transistor Tj per column Cj, for each column Cj, the signal Selj comprises only one component supplied to the gate of transistor Tj. By way of another example, when the block 1 comprises a plurality of transistors Tj per column Cj, for each column Cj, the signal Selj comprises a plurality of components each applied to the gate of one of the transistors Tj.

The circuit 110 receives a signal Sig1 indicating, for each writing operation, which columns Cj are to be selected during that writing operation, or, put another way, which columns Cj are to be written during that writing operation. The circuit 110 also receives a signal Sig2 controlling the writing operation. For example, the signal Sig2 indicates the start of the write current pulses flowing in the selected columns during the writing operation. By way of example, the signal Sig2 also indicates the end of the write current pulses flowing in the selected columns during the writing operation.

Although not detailed in FIG. 1, the circuit 110 may receive other signals. For example, the circuit 110 may receive one or more selection coordination signals and/or a write mode activation signal.

Although not detailed in FIG. 1, when writing to a plurality of columns simultaneously, the block 1 is configured such that the pulses flowing through the selected columns all have the same shape, which determines the programmed state in the memory cells addressed during this writing operation. This pulse shape depends on the current Iref and, for example, on the signal Sig2 as regards the pulse duration. For example, pulses used to program an amorphous state of the phase-change material have a shape with an abrupt edge at the end of the pulse. Conversely, pulses used to program a crystalline state of the phase-change material have, for example, a shape presenting, at the end of the pulses, a slowly transitioning edge compared with the aforementioned abrupt edge.

A disadvantage of the block 1 described above is as follows. At the start of a writing operation in several columns Cj simultaneously, the transistors Tj in these columns are switched on by circuit 110 by means of signals Selj. This results in a voltage variation on rail 108, for example a voltage drop. This voltage variation at the start of the write current pulses alters the shape of the write current pulses relative to a target shape.

In addition, the value (amplitude) of this voltage variation on rail 108 depends on the number of selected columns Cj as shown in FIG. 2, this dependence of the voltage variation on rail 108 on the number of selected columns Cj being undesirable.

FIG. 2 shows a curve 200 showing the variation in voltage on rail 108 (ordinate) at the start of write current pulses in selected columns, as a function of the number of selected columns (abscissa).

As shown in curve 200, the amplitude of the voltage variation on rail 108 increases with the number of columns selected during a writing operation.

To overcome the disadvantages of the memory block 1, it is proposed herein to add a compensation circuit configured to supply, at the start of the write current pulses in the selected columns Cj, a compensation current pulse having an amplitude that depends on the number of selected columns Cj.

This current pulse is configured to compensate for the voltage variation on rail 108, such that the voltage on rail 108 remains as stable as possible at the start of the write current pulses. In this way, the write current pulses have the desired shape, which is determined by the current value Iref, and by the signal Sig2.

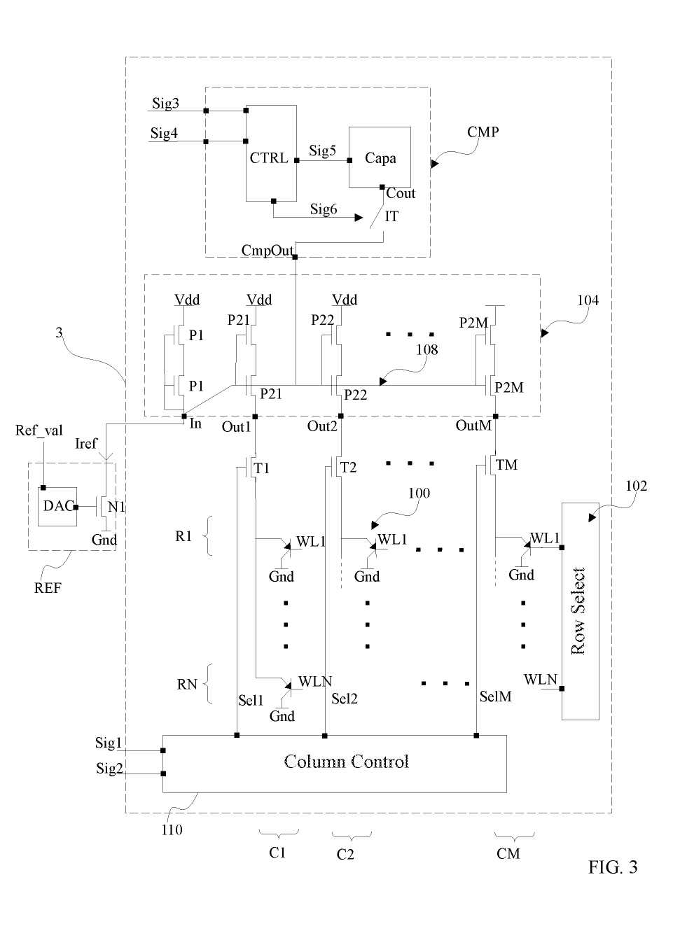

FIG. 3 shows an example of such an embodiment of a PCM memory block 3.

The memory block 3 has many elements in common with the memory block 1, and only the differences between these two memory blocks are highlighted here. In particular, unless otherwise indicated, everything previously stated in relation to the memory block 1 applies to the memory block 3.

Compared with the memory block 1, the memory block circuit 3 includes a compensation circuit CMP.

The circuit CMP is configured to receive a signal Sig3. The signal Sig3 indicates the number of columns Cj selected for a reading step. For example, the Signal Sig3 indicates which columns Cj have been selected, and therefore the number of columns Cj selected. The signal Sig3 enables the circuit CMP to determine the maximum amplitude of the compensation current pulse such that it compensates for the variation, for example the drop, in the voltage of rail 108 at the start of the write current pulses.

By way of example, when the current Iref has a fixed maximum value irrespective of the writing operation considered, that is when the write current pulses have an identical maximum amplitude irrespective of the writing operation considered, the signal Sig3 is, for example, entirely determined by the signal Sig1, and is, for example, identical to this signal Sig1 or is representative of a single value equal to the number of selected columns Cj.

By way of another example, when the current Iref has a maximum value that depends on the writing operation being considered, that is when the write current pulses have a maximum amplitude which varies according to the writing operation being considered, the signal Sig3 is, for example, at least partly determined by the signal Sig1 and by the maximum value of the current Iref for the writing operation being considered.

The circuit CMP is also configured to receive a signal Sig4 indicating the start of the write current pulses in the columns Cj selected for the writing operation, that is, the start time of these write current pulses. This signal Sig4 enables the synchronization of the start of the compensation current pulse with the start of the write current pulses. Thus, the signal Sig4 determines the start of the compensation current pulse.

For example, the signal Sig4 is at least partly determined by the signal Sig2.

For example, the signal Sig4 comprises the signal Sig2 and an indication of a delay, for example programmable during a calibration phase, between an edge of the signal Sig2 triggering the start of the write current pulses and the start of the current compensation pulse. Alternatively, the signal Sig4 is determined solely by the signal Sig2, and is, for example, identical to the signal Sig2. As yet another example, the signal Sig4 corresponds to the concatenation of the signals Selj, these signals Selj being at least partly determined by the signal Sig2.

Based on the received signals Sig3 and Sig4, the circuit CMP determines what should be the shape of the compensation current pulse and, more specifically, the time at which it should start and the amplitude that it should have. In other words, the circuit CMP is configured to supply the conductive rail 108, at the start of the write current pulses, with a compensation current pulse determined by the signals Sig3 and Sig4.

Although not illustrated in FIG. 3, in some embodiments, the circuit CMP receives a signal for selectively activating and deactivating the compensation, that is, a signal indicating whether or not the circuit CMP should provide a compensation current pulse for the writing operation under consideration.

By way of example, in FIG. 3, the circuit 104 comprises two P1 transistors and, for each column, two P2j transistors, it being understood that the circuit 104 could have been implemented in the manner illustrated in FIG. 1, or with a number of P1 transistors and a number of P2j transistors different from those in the examples of FIGS. 1 and 3.

According to one embodiment, the circuit CMP comprises a single CmpOut output configured to supply the compensation current pulse, this CmpOut output being connected to the rail 108.

According to one embodiment, the circuit CMP comprises capacitors connected in parallel and is configured to provide the compensation current pulse by discharging these capacitors onto rail 108 at the start of the write current pulses. In this case, the amplitude of the compensation current pulse is determined by the number of capacitors that the circuit CMP will couple to rail 108 at the start of the write current pulses, and which will discharge and supply charge to rail 108. The number of capacitors selected and the time at which the selected capacitors begin to discharge onto the rail 108 are controlled by the circuit CMP based on the signals Sig3 and Sig4.

For example, the circuit CMP comprises, as shown in FIG. 3, a circuit Capa comprising a plurality of capacitors (not shown in FIG. 3). Each capacitor of the circuit Capa is connected to a Cout output node of the circuit Capa via a switch (not shown in FIG. 3). Put another way, the circuit Capa comprises a plurality of capacitors in parallel, each connected to the node Cout by a corresponding switch. The node Cout is coupled to the output CmpOut, preferably via a switch IT as shown in FIG. 3, although in other examples not shown, this node Cout may be directly connected to the output CmpOut. The circuit CMP is configured to pre-charge the capacitors of the circuit Capa prior to the writing operation, and to electrically couple selected capacitors to the output CmpOut at the start of the compensation current pulse.

For example, the circuit CMP is configured to determine which capacitors to select as a function of the signal Sig3, that is to determine which capacitors to select so that the compensation current pulse compensates for the voltage variation on rail 108 at the start of the write current pulse.

By way of example, for each selected capacitor, the circuit CMP is configured to control the closing of the switch coupling this capacitor to the node Cout. In the example shown in FIG. 3, where the circuit CMP includes the switch IT, this closing of the selected capacitor switches is implemented before the start of the write current pulses, and then the circuit CMP controls the closing of the switch IT at the start of the write current pulses in order to cause the start of the compensation current pulse. In another non-illustrated embodiment, in the case that the circuit CMP does not include the switch IT, the circuit CMP controls the closing of the selected capacitor switches at the start of the write current pulses. However, in the absence of the switch IT, due to possible desynchronization of the closing of these switches, the compensation current pulse may have a shape that is more different from a target shape than in the case where the switch IT is present.

By way of example, the switches connecting the capacitors of the circuit Capa to the node Cout are controlled by a signal Sig5 generated by the circuit CMP based on the signal Sig3, for example by a circuit CTRL in the circuit CMP. For example, the signal Sig5 is configured to control the open or close state of each of these switches, independently of the open or close state of the other switches.

By way of example, the switch IT is controlled by a signal Sig6 generated by the circuit CMP based on signal Sig4, for example by the circuit CTRL of the circuit CMP.

FIG. 4 illustrates an example of the circuit 110 shown in FIG. 3.

In this example, the circuit 110 comprises a logic circuit 400 implementing a Boolean AND function between the signals Sig1 and Sig2, and providing the set of signals Selj (Sel<1..M> in FIG. 4) corresponding to the result of this Boolean function.

In this example, the signal Sig1 is an M-bit signal, each bit of the signal Sig1 corresponding to a column Cj and being in logic state '1' when the corresponding column Cj is to be selected during the reading step. In this example, the signal Sig2 is a binary signal switching from logic state '0' to logic state '1' to indicate (control) the start of write current pulses, and from logic state '1' to logic state '0' to indicate (control) the end of write current pulses, if not caused by setting current Iref to zero. The Sel<1..M> signal then corresponds to a signal of M bits, each bit corresponding to a signal Selj and being the result of a Boolean AND between the bit of the signal Sig1 corresponding to the Cj column and the signal Sig2. In other words, the Sel<1..M> signal corresponds to the concatenation of the signals Selj.

Of course, the person skilled in the art will be able to envisage other examples implementations of the circuit 110 from the previously given functional description of the circuit 110, for example in the case where the circuit 110 receives one or more selection coordination signals and/or a write mode activation signal.

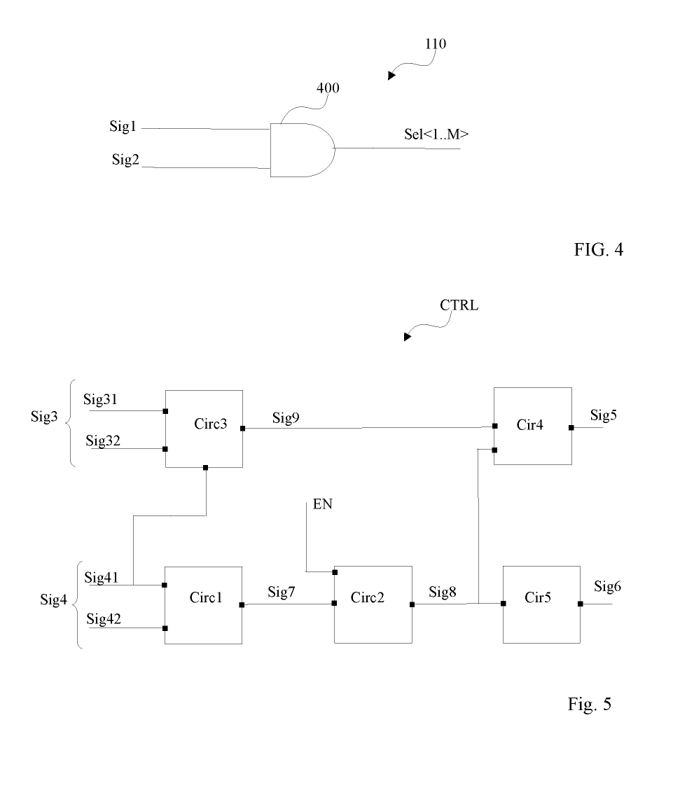

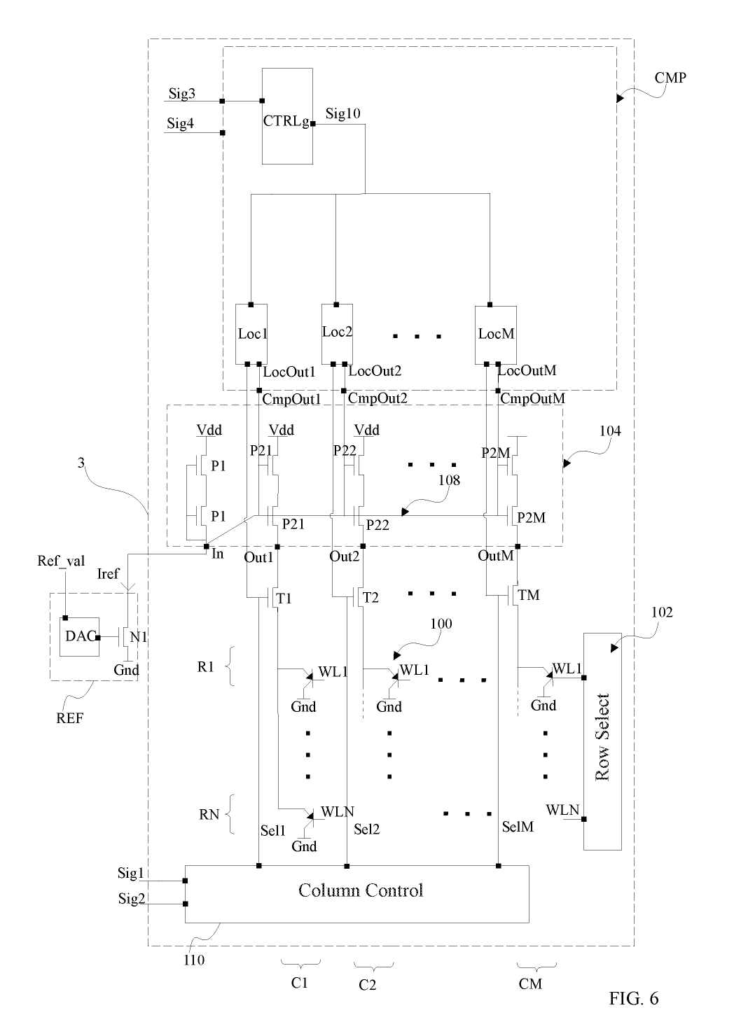

FIG. 5 shows an example of the implementation of the circuit CTRL in the circuit CMP shown in FIG. 3. In this example, the circuit CTRL receives signals Sig3 and Sig4, and supplies signals Sig5 and Sig6.

In this example, the signal Sig3 includes an indication (or signal) Sig31 indicating the number of columns Cj selected. For example, the signal Sig31 is identical to signal Sig1. Furthermore, in this example, the maximum value of the amplitude of the write current pulses depends on the writing operation being considered, and the signal Sig3 further comprises an indication (or signal) Sig32 indicating this maximum amplitude value.

In addition, in this example, the signal Sig4 includes an indication (or signal) Sig41 indicating the start of the write current pulses. For example, the signal Sig41 is identical to the signal Sig2. Furthermore, in this example, the signal Sig4 comprises an indication (or signal) Sig42 determining a delay, preferably programmable during a calibration step, between an edge of the signal Sig41 corresponding to a control of the start of the write pulses, and the start time of the corresponding compensation current pulse to be supplied by the circuit CMP.

In this example, the circuit CMP also receives a signal Sig41 for selective activation of the compensation, that is, a signal for selectively activating the circuit CMP.

The circuit CMP includes a circuit Circ1 configured to receive the signals Sig41 and Sig42, and to provide a signal Sig7 corresponding to the signal Sig41 delayed by a time determined by the signal Sig42. In other non-illustrated examples in which the signal Sig4 does not include the indication Sig42 of a delay, the circuit Circ1 may be omitted and the signal Sig5 then corresponds to the signal Sig4. In still other, non-illustrated examples in which the signal Sig4 does not include the indication Sig42 of a delay, this delay can be hard-coded in the circuit Circ1. In yet another example in which the signal Sig4 indicates the start time of the write current pulses and therefore does not include an indication Sig42, the circuit Sig7 can be omitted and the signal Sig7 then corresponds to the signal Sig4.

In the present example in which the circuit CMP receives the signal EN, the circuit CMP comprises a circuit Circ2 configured to receive the signal Sig7 and the signal EN, and to supply a signal Sig8. The signal Sig8 indicates when the switches of the capacitors to be selected in the circuit Capa are switched on to select these capacitors, it being understood that, in the case where the signal EN indicates that compensation is to be deactivated, the signal Sig8 does not indicate any time for turning on these switches. In other, non-illustrated examples, where the circuit CMP does not receive the signal EN, the circuit Circ2 can be omitted and the signal Sig8 then corresponds to the signal Sig7.

The circuit CMP includes, in the present example, a circuit Circ3 configured to receive the signal Sig3, that is, the signals Sig31 and Sig32 in the example of FIG. 5, and to supply a signal Sig9 indicating which capacitors in the circuit Capa are to be selected, that is, which switches coupling the capacitors of the circuit Capa to the node CmpOut (FIG. 3) are to be switched on.

The circuit CMP also comprises, in this example, a circuit Circ4 configured to receive the signals Sig8 and Sig9, and to supply the signal Sig5 based on these signals Sig7 and Sig8. For example, the signal Sig5 corresponds to the signal Sig9 when the signal Sig8 is in a state indicating that the switches of the capacitors selected in the circuit Capa are to be controlled to be in the closed state.

In this example, where the circuit CMP supplies the signal Sig6 for controlling the switch IT determining (controlling) the start of the compensation current pulse, the circuit CMP comprises a circuit Circ5 configured to receive the signal Sig8 and to supply the signal Sig6 based on the signal Sig8. For example, the signal Sig6 corresponds to the signal Sig8 delayed by a fixed delay or a delay that is programmable, for example during a calibration step of the circuit CMP.

In the embodiment of the circuit CMP described in relation to FIG. 3, the compensation current pulse is supplied by a single output CmpOut of the circuit CMP, and is therefore supplied to the rail 108 at a node connecting this rail 108 to the output CmpOut.

In alternative embodiments, it may be desirable, in order to improve compensation quality, for the circuit CMP to supply the compensation current pulse in the form of a plurality of compensation current sub-pulses, each sub-pulse corresponding to a different selected column Cj and being supplied directly to the gate of the MOS transistor(s) P2j corresponding to that column Cj.

FIG. 6 shows an example of such a variant of the memory block 3.

The memory block 3 in FIG. 6 has many elements in common with that in FIG. 3, and only the differences between these two memory blocks 3 are highlighted here. Thus, unless otherwise indicated, all that has been previously indicated for the memory block 3 described in relation to FIG. 3 applies to the memory block of FIG. 6.

Compared with the memory block 3 in FIG. 3, the circuit CMP in the memory block in FIG. 6 has M outputs CmpOutj, each corresponding to a different column Cj. For each column Cj, the output CmpOutj of the circuit CMP is connected to the gate of the transistor or transistors P2j corresponding to that column.

Furthermore, in FIG. 6, the signal Sig3 includes, for each column Cj, an indication of whether or not column Cj is selected.

The present circuit CMP is configured to provide, for each column Cj, a compensation current sub-pulse starting with the compensation current pulse (that is, with the write current pulses) if this column Cj is selected. Thus, according to one embodiment, the circuit CMP comprises M sub-circuits Locj corresponding respectively to the M columns Cj. For each column Cj, the circuit Locj corresponding to this column Cj has an output connected to the output CmpOutj of the circuit CMP and is configured to supply this output CmpOutj with a compensation current sub-pulse starting with the compensation current pulse if, and only if, this column Cj is selected. By way of example, the circuits Locj are all identical.

According to one embodiment, for each column Cj, the indication that the column Cj is or is not selected can be included in the signal Sig3, for example when this signal Sig3 corresponds at least in part to the signal Sig2.

According to one embodiment, for each column Cj, the indication that this column Cj is selected or not corresponds to the signal Selj of the column, and the signal Sig4 comprises all of the signals Selj. FIG. 6 shows both the signal Sig4 supplied to the circuit CMP, and the signals Selj supplied to the circuit CMP, although in such an embodiment the signal Sig4 actually corresponds to the signals Selj. For each column Cj, the signal Selj for that column is then, for example, supplied to the corresponding circuit Locj.

One advantage of the signal Sig4 comprising all of the signals Selj is that these signals Selj can be used as a synchronization signal to control the start of the compensation current sub-pulses, and thus of the compensation current pulse, relative to the start of the write current pulses. In particular, when a column Cj is selected, this makes it possible to synchronize the start of the compensation current sub-pulse corresponding to this column Cj with the start of the write current pulse flowing in this column Cj.

According to one embodiment, each circuit Locj comprises a plurality of parallel-coupled capacitors, each connected to an internal node of the circuit Locj by a switch. Optionally, and preferably, each circuit Locj includes a switch ITloc connecting its internal node to the output LocOutj of the circuit Locj, thus to the output Cmpoutj of the circuit CMP. Each circuit Locj is configured to pre-charge its capacitors before a writing operation, and to close its switch IT at the start of the write current pulses if the column Cj corresponding to this sub-circuit Locj is selected, that is, at the moment when the compensation current sub-pulse supplied by this circuit Locj is due to start when the corresponding column Cj is selected, or, put another way, at the moment when the compensation current pulse comprising all of the compensation current sub-pulses is due to start. In addition, each circuit Locj is configured to control the conducting state of the switches coupling the selected capacitors, preferably before switching on its IT switch, if the column Cj corresponding to this circuit Cj is selected.

By way of example, the circuit CMP is configured, based on the signal Sig3, to indicate to each circuit Locj which capacitors this circuit should select, this indication preferably being identical for all the circuits Locj.

For example, each circuit Locj receives the same signal Sig10 indicating to it which capacitors to select, this signal Sig10 being determined based on the signal Sig3, for example by a circuit CTRLg in the circuit CMP. The circuit CTRLg is, for example, similar to the circuit CTRL described above, with the difference that it comprises only the circuit Circ3 and that the signal Sig10 it supplies corresponds to the concatenation of the signals EN and Sig9.

By way of example, each sub-circuit Locj receives the corresponding signal Selj, and switches its switch IT on when the signal Selj indicates that the transistor(s) Tj is/are switched on, thus improving compensation synchronization by synchronizing each column Cj locally.

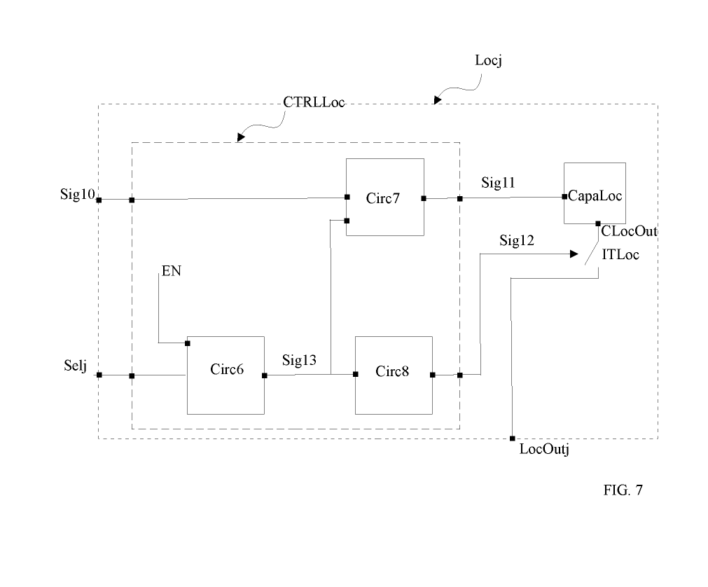

FIG. 7 shows an example of a circuit Locj for the case in which the circuit Locj receives the signal Sig10 and the signal Selj.

As shown in FIG. 7, the circuit Locj includes a circuit CapaLoc comprising a plurality of capacitors (not shown in FIG. 7). Each capacitor of the circuit CapaLoc is connected to an output node CLocOut of the circuit CapaLoc via a switch (not shown in FIG. 7). Put another way, the circuit CapaLoc comprises a plurality of capacitors connected in parallel, each connected to the node CLocOut by a corresponding switch. The node CLocOut is coupled to the output LocOutj, preferably via a switch ITLoc as shown in FIG. 7. The circuit Locj is configured to pre-charge the capacitors of its circuit CapaLoc prior to the writing operation, and to electrically couple selected capacitors to the output LocOutj at the start of the compensation current pulse.

For example, the circuit Locj is configured to determine which capacitors to select based on the signal Sig10.

By way of example, for each selected capacitor, the circuit Locj is configured to control the closing of the switch coupling this capacitor to the node CLocout. In the example shown in FIG. 7 according to which the circuit Locj includes the switch ITLoc, this closing of the selected capacitor switches is implemented before the start of the write current pulses, and the circuit Locj then controls the closing of the switch ITLoc at the start of the write current pulses.

For example, the switches connecting the capacitors of the circuit Capa to the CLocOut node are controlled by a signal Sig11 generated by the circuit Locj from the Sig10 signal, for example by a circuit CTRLLOC in the circuit Locj. For example, the signal Sig11 is configured to control the open or close state of each of these switches, independently of the open or close state of the others of these switches.

For example, the switch ITLoc is controlled by a signal Sig12 generated by the circuit Locj based on the signal Selj, for example by the circuit CTRLLoc of the circuit Locj.

An example of the circuit CTRLLOC is shown in FIG. 7.

In this example, the signal EN is included in the signal Sig10, and the circuit CTRLLOC comprises a circuit Circ6 configured to receive the signal Selj and the signal EN. The circuit Circ6 is configured to provide, based on the signal Selj, a signal Sig13 indicating which switches coupling selected capacitors of the circuit CapaLoc to the node CLocOut are to be switched on. For example, the circuit implements a Boolean AND logic function between the signals Selj and EN when the logic '1' state of the signal Selj controls the corresponding transistors Tj to be switched on, and the logic '1' state of the signal EN controls the compensation to be activated. Thus, when signal EN is in logic state '0' indicating that compensation is deactivated, or when signal Selj is in logic state '0' indicating that the corresponding column Cj is not selected, the signal Sig13 does not indicate any instant at which the switches are to be switched to the conductive state.

In other examples not shown in which the circuit Locj does not receive the signal EN, the circuit Circ6 can be omitted and the signal Sig13 then corresponds to the signal Selj.

The circuit Locj includes, in the present example, a circuit Circ7 configured to receive the signal Sig10 indicating which capacitors are to be selected in the circuit CapaLoc. The circuit Circ7 also receives the signal Sig13. The circuit Circ7 supplies the signal Sig11 based on the signals Sig13 and Sig10, that is, based on the signals Sig10 and Selj. For example, the signal Sig11 corresponds to signal Sig10 when signal Sig13 is in a state indicating that the switches of the capacitors selected in the circuit CapaLoc are to be controlled in the closed state.

The circuit CMP also comprises, in this example, a circuit Circ8 configured to receive the signal Sig13 and to supply the signal Sig12 based on the signal Sig13. For example, the signal Sig12 corresponds to a delayed version of the signal Sig13.

Although an example of the circuit Locj has been described in relation to FIG. 7, the person skilled in the art will be able to foresee other examples of implementation of the circuit Locj from the functional description of this circuit Locj provided above.

Various embodiments and variants have been described. Those skilled in the art will understand that certain features of these embodiments can be combined and other variants will readily occur to those skilled in the art. In particular, the implementation of the circuit CMP is not limited to the examples described above, and the person skilled in the art will be able to foresee other implementations of this circuit, whether it is configured to supply the compensation current pulse on a single output CmpOut of the circuit CMP connected to the rail 108, or for the compensation current pulse to be supplied in the form of a plurality of compensation current sub-pulses, each of these sub-pulses being supplied by a corresponding output CmpOutj, only if the column Cj corresponding to this output is selected during the writing operation.

Finally, the practical implementation of the embodiments and variants described herein is within the capabilities of those skilled in the art based on the functional description provided hereinabove. In particular, the person skilled in the art will be capable of implementing the circuits Capa and CapaLoc.

1. A memory block, comprising:
a plurality of phase-change memory cells arranged in rows and columns;
a first circuit comprising:
a first MOS transistor coupling a supply voltage to an input of the first circuit configured to receive a reference current, said first MOS transistor having a gate connected to said input;
for each column, at least one second transistor coupling the supply voltage and a corresponding output of the first circuit that is coupled to said column; and
a conductive rail connecting said input to a gate of each second transistor;
for each column, at least one third MOS transistor coupling said column to the corresponding output of the first circuit; and
a second circuit configured to:
receive a first signal indicating which columns are to be written during a writing operation;
receive a second control signal controlling the writing operation; and
control each third MOS transistor based on the first and second signals, such that, during the writing operation, a write current pulse flows in each selected column;
a third circuit configured to:
receive a third signal indicating a number of selected columns and a fourth signal indicating a start of write current pulses in the selected columns for the writing operation; and
supply to the conductive rail, at a start of the write current pulses for the writing operation, a pulse of compensation current determined by the third and fourth signals.

2. The memory block according to claim 1, wherein the pulse of compensation current, as determined based on the third and fourth signals, compensates for a voltage variation on said rail resulting from switching each third MOS transistor of the selected columns to a conductive state at the start of the write current pulses for the writing operation.

3. The memory block according to claim 1, wherein, for each column, said at least one second MOS transistor coupling the supply voltage and the corresponding output of the first circuit is arranged in a current mirror configuration with said first MOS transistor.

4. The memory block according to claim 1, wherein the fourth signal determines a start of the compensation current pulse, and the third signal determines a maximum value of the compensation current pulse.

5. The memory block according to claim 1, wherein the third signal comprises an indication of a maximum value of the write current pulses during the writing operation.

6. The memory block according to claim 1, wherein the second signal indicates a start and an end of the write current pulses flowing in the selected columns.

7. The memory block according to claim 6, wherein the fourth signal is determined at least in part by the second signal.

8. The memory block according to claim 1, wherein the third circuit is further configured to receive a signal for selectively activating and deactivating the supply of the compensation current pulse to said conductive rail.

9. The memory block according to claim 1, wherein the third circuit comprises a single output connected to said conductive rail and configured to provide said compensation current pulse.

10. The memory block according to claim 9, wherein the third circuit comprises a plurality of parallel capacitors each coupled to a first node by a first switch, and a second switch coupling the first node to the output of the third circuit, the third circuit being configured to: pre-charge the capacitors prior to the writing operation; close the second switch at the start of the compensation current pulse, and close all or some of the first switches prior to the closure of the second switch based on the third signal.

11. The memory block according to claim 1, wherein:
the third circuit comprises, for each column, a corresponding output connected to the gate of said at least one second MOS transistor coupled to said column;
the third circuit comprises, for each column, a sub-circuit configured to supply to the output of the third circuit corresponding to that column, a first current pulse starting with the compensation current pulse if said column is selected; and
the compensation current pulse corresponds to the set of first pulses.

12. The memory block according to claim 11, wherein:
each sub-circuit comprises:
a plurality of parallel capacitors each coupled to a first node of said sub-circuit by a first switch; and
a second switch coupling said first node of said sub-circuit to the output of the third circuit to which this sub-circuit is connected; and
each sub-circuit is configured to:
pre-charge said capacitors before the writing operation;
close its second switch at the start of the compensation current pulse if the column corresponding to the sub-circuit is selected; and
close all or some of the first switches before closing the second switch based on the third signal.

13. The memory block according to claim 12, wherein, for each column, the sub-circuit corresponding to the column is configured to receive a control signal from said at least one third switch corresponding to the column, and to control the switching of its second switch to the conducting state based on the control signal.

14. A memory comprising:
the at least one memory block according to claim 1; and
a circuit configured to supply the reference current.
